(19) United States
(12) Patent Application Publication
(10) Pub. No.: US 2010/0164758 A1
(43) Pub. Date: Jul. 1, 2010

(54) KEYPAD ASSEMBLY

(75) Inventor: SONG-LING YANG, Shenzhen City (CN)

Correspondence Address: PCE INDUSTRY, INC.;ATT. Steven Reiss, 288 SOUTH MAYO AVENUE, CITY OF INDUSTRY, CA, 91789, US

(73) Assignees: HONG FU JIN PRECISION INDUSTRY (ShenZhen) CO., LTD, Shenzhen City (CN); HON HAI PRECISION INDUSTRY CO., LTD., Tu-Cheng (TW)

(21) Appl. No.: 12/468,055

(22) Filed: May 19, 2009

(30) Foreign Application Priority Data
Dec. 29, 2008 (CN) 200810306621.7

(51) Int. Cl. H03M 11/00

(52) U.S. Cl. 341/22

(57) ABSTRACT

A keypad assembly includes a base, a crown, a resistance member, a conductive member, a detecting unit, and a control unit. The crown is movably received in the base. The resistance member is received in the base and positioned under the crown. The conductive member is disposed on the bottom of the crown and positioned above the resistance member. The detecting unit is electrically connected with the conductive member and configured for locating the position on the resistance member contacted by the conductive member when the crown is pressed. The control unit is electrically connected with the detecting unit and configured for executing a corresponding command base upon the determination of the detecting unit.

### BACKGROUND

1. Technical Field

The present disclosure relates to keypad assemblies and, particularly, to a keypad assembly used in an electrical device.

2. Description of Related Art

Command keys have been widely used in electrical devices, such as digital cameras, to execute various commands. However, to accommodate a number of commands on a command key, complicated circuit arrangements are required, such that cost and size are substantially and undesirably increased.

Therefore, it is desirable to provide a keypad assembly used in an electrical device which can overcome or at least alleviate the above-mentioned problem.

### BRIEF DESCRIPTION OF THE DRAWINGS

FIG. 1 is a schematic exploded view of a keypad assembly according to an exemplary embodiment.

FIG. 2 is similar to FIG. 1, but showing the keypad assembly from another angle.

FIG. 3 is a schematic isometric view of the keypad assembly of FIG. 1.

FIG. 4 is a partly isometric view of the keypad assembly of FIG. 3 taken along IV-IV line.

### DETAILED DESCRIPTION

Embodiments of the disclosure will now be described in detail with reference to the accompanying drawings.

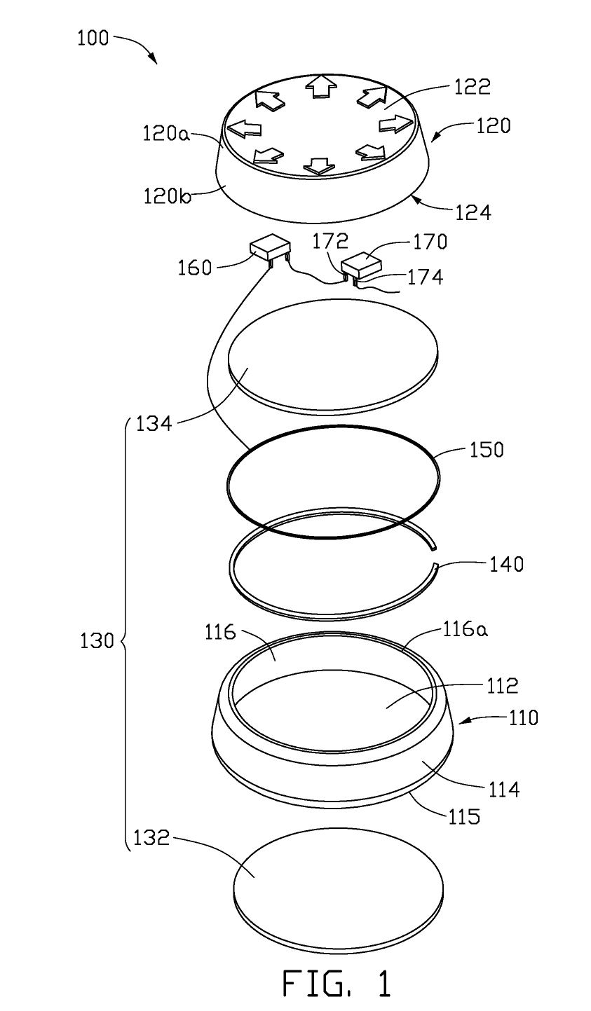

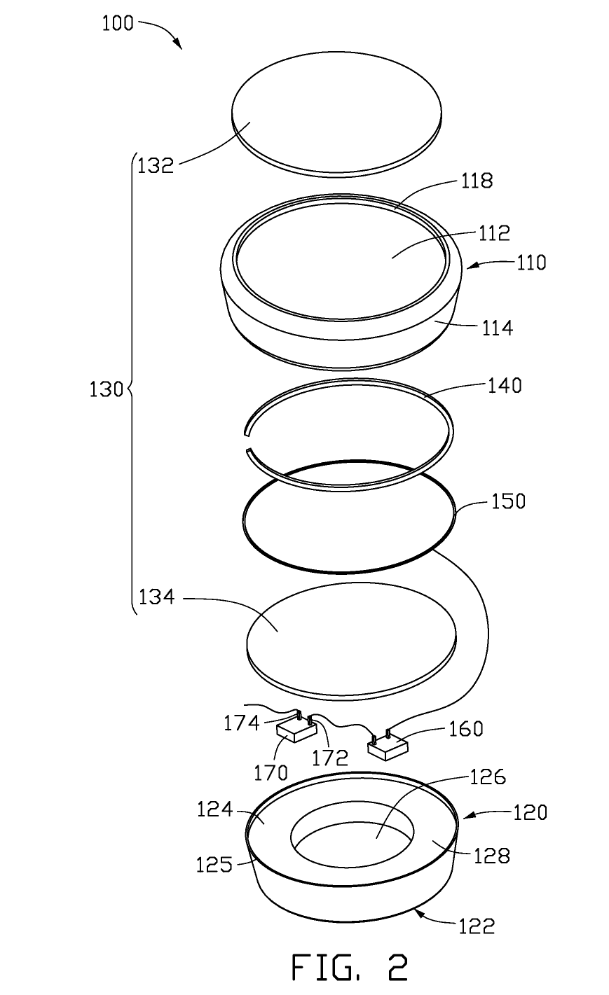

Referring to FIGS. 1-2, a keypad assembly 100 according to an exemplary embodiment includes a base 110, a crown 120, a supporting member 130, a resistance member 140, a conductive member 150, a detecting unit 160, and a control unit 170.

The base 110 includes a bottom portion 112, a sidewall 114, and a first flange 115. The sidewall 114 is disposed along the periphery of the bottom portion 112, and with the bottom portion 112, cooperatively define a first receiving space 116 having an opening 116a to receive the crown 120 and the resistance member 140. In this embodiment, the sidewall 114 is substantially a frustum of a cone and the distal end of the sidewall 114 is tapered. The first flange 115 extends from the bottom portion 112 along a direction away from the bottom portion 112 to define a second receiving space 118.

The crown 120 is movably received in the first receiving space 116. When the crown 120 is received in the first receiving space 116, a portion of the crown 120 protrudes out from the first receiving space 116.

The crown 120 includes a first surface 122, a second surface 124 on another side of the crown 120 opposite to the first surface 122, and a second flange 125. In this embodiment, the crown 120 is substantially a frustum of a cone corresponding to the first receiving space 116 and includes a bottom end 120a and a tapered end 120b. The tapered end 120b is opposite to the bottom end 120a and away from the first surface 122. The bottom end 120a has a radius equal to that of the opening 116a of the first receiving space 116 to prevent the crown 120 from disengaging with the base 110. A number of icons are etched on the first surface 122 to assist/guide operating the keypad assembly 100. A third receiving space 126 is defined in the second surface 124 for receiving the detecting unit 160 and the control unit 170. The second flange 125 extends from the second surface 124 away from the first surface 122. The second flange 125 and the second surface 124 cooperatively define a fourth receiving space 128 communicating with the third receiving space 126. In this embodiment, the second flange 125 is substantially circular.

The supporting member 130 includes a first magnet 132 and a second magnet 134. The first magnet 132 is received in the second receiving space 118 of the base 110. The second magnet 134 is received in the fourth receiving space 128 of the crown 120. In this embodiment, the first and second magnets 132 and 134 are secured to the base 110 and the crown 120 via adhesive. In this embodiment, the first and second magnets 132 and 134 are substantially circular. When the supporting member 130 is assembled on the base 110 and crown 120, the first and second magnets 132 and 134 are respectively received in the second and fourth receiving spaces 118 and 128, with the polarity of the first magnet 132 adjacent to the bottom portion 112 of the base 110 the same as that of the second magnet 134 away from the second surface 124 of the crown 120, such as the positive polarity of the first magnet 132 faces the positive polarity of the second magnet 134. As a result the first and second magnets 132 and 134 repel each other to levitate the crown 120 in the base 110 and above the bottom portion 112 of the base 110.

The resistance member 140 is received in the first receiving space 116 of the base 110 and positioned under the crown 120. The resistance member 140 is substantially a C-shaped arc. An end of the resistance member 140 is connected to a power source (not shown), and the other end of the resistance member 140 is grounded. The resistance member 140 has linear resistance.

The conductive member 150 is received in the fourth receiving space 128 of the crown 120 and positioned above the resistance member 140. In this embodiment, the conductive member 150 is substantially annular. When the crown 120 is received in the first receiving space 116 and not pressed, the conductive member 150 and the resistance member 140 are spaced from each other. When the crown 120 is pressed, the conductive member 150 contacts the resistance member 140.

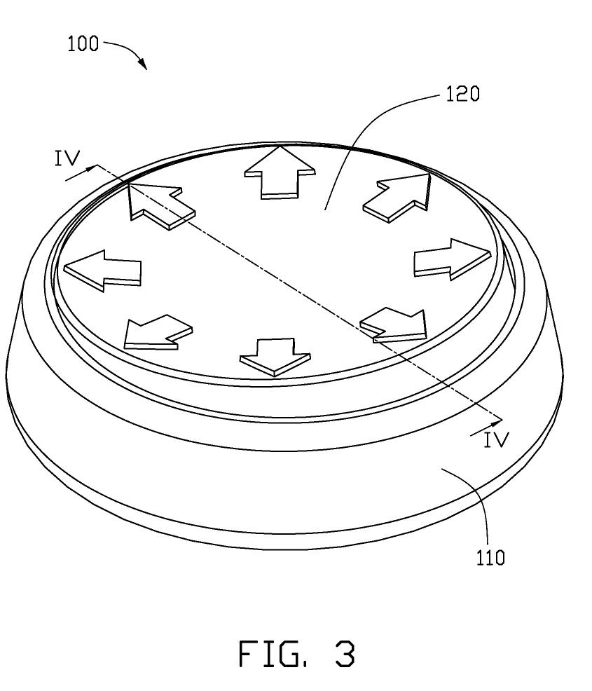

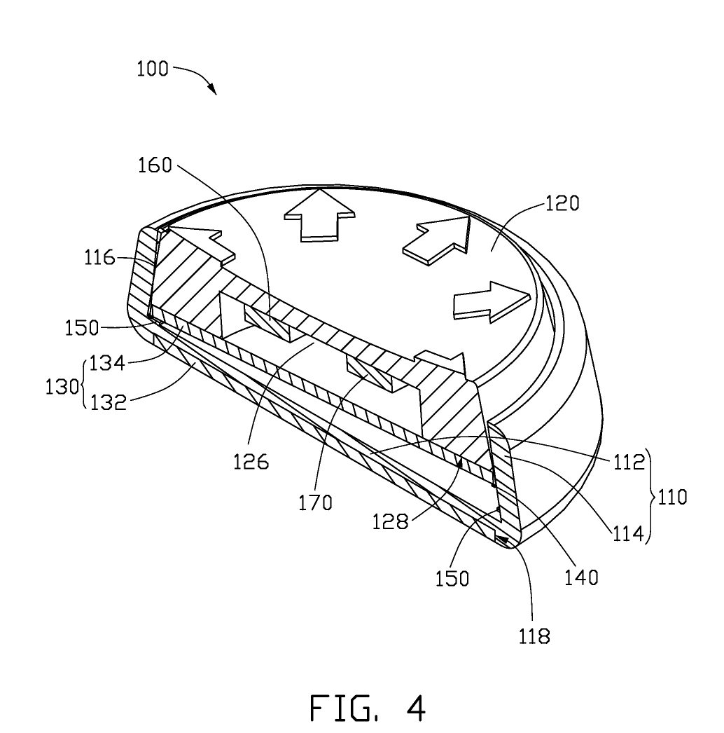

Referring to FIGS. 3-4, the detecting unit 160 is received in the third receiving space 126 of the crown 120 and is electrically connected to the conductive member 150. The detecting unit 160 is configured for locating the position on the resistance member 140 contacted by the conductive member 150 when the crown 120 is pressed. In this embodiment, the detecting unit 160 detects a voltage of the resistance member 140 to determine the contacted position.

The control unit 170 is received in the third receiving space 126 of the crown 120 and electrically connected to the detecting unit 160. The control unit 170 stores a number of predetermined commands corresponding to the positions on the resistance member 140. The control unit 170 executes a corresponding command based upon the position detected by the detecting unit 160. In this embodiment, the control unit 170 includes an input end 172 and an output end 174. The input end 172 is electrically connected to the detecting unit 160, and the output end 174 is electrically connected to an outer device (not shown) to control the outer device to execute corresponding function, such as the control unit 170 control a digital camera to boot up or capture image.

The keypad assembly 100 can execute various commands based upon the corresponding position on the resistance member 140 contacted by the conductive member 150 when the crown 120 is pressed, therefore the keypad assembly 100 has a compacted structure and a low cost.

It is to be understood, however, that even though numerous characteristics and advantages of the embodiments have been set forth in the foregoing description, together with details of the structures and functions of the embodiments, the disclosure is illustrative only, and changes may be made in detail, especially in matters of arrangement of parts within the principles of the invention to the full extent indicated by the broad general meaning of the terms in which the appended claims are expressed.

What is claimed is:

1. A keypad assembly comprising:
a base;
a crown movably received in the base;
a resistance member received in the base and positioned under the crown;
a conductive member disposed on the bottom of the crown and positioned above the resistance member;
a detecting unit electrically connected with the conductive member and configured for locating the position on the resistance member contacted by the conductive member when the crown is pressed; and
a control unit electrically connected with the detecting unit and configured for executing a corresponding command base upon the determination of the detecting unit.

2. The keypad assembly of claim 1, wherein the resistance member is substantially a C-shaped arc.

3. The keypad assembly of claim 1, wherein the conductive member is substantially annular.

4. The keypad assembly of claim 1, wherein the base comprises a bottom portion and a sidewall disposed along the periphery of the bottom portion, and with the bottom portion cooperatively define a first receiving space having an opening to receive the crown and the resistance member.

5. The keypad assembly of claim 4, wherein the sidewall of the base is substantially a frustum of a cone and the distal end of the sidewall is tapered.

6. The keypad assembly of claim 5, further comprising a supporting member, wherein the base further comprises a first flange extending from the bottom portion of the base along a direction away from the bottom portion to define a second receiving space, and the supporting member comprises a first magnet received in the second receiving space.

7. The keypad assembly of claim 6, wherein the crown comprises a first surface and a second surface on another side of the crown opposite to the first surface, and the second surface defines a third receiving space for receiving the detecting unit and the control unit.

8. The keypad assembly of claim 7, wherein the crown further comprises a second flange extending from the second surface of the crown away from the first surface of the crown, and with the second surface of the crown cooperatively define a fourth receiving space communicating with the third receiving space, and the supporting member further comprises a second magnet received in the fourth receiving space.

9. The keypad assembly of claim 8, wherein the second flange is substantially circular.

10. The keypad assembly of claim 8, wherein the first and second magnets are respectively secured to the base and the crown via adhesive.

11. The keypad assembly of claim 8, wherein the first and second magnets are substantially circular.

12. The keypad assembly of claim 8, wherein the polarity of the first magnet adjacent to the bottom portion of the base is the same as that of the second magnet away from the second surface of the crown.

13. The keypad assembly of claim 7, wherein the crown is substantially a frustum of a cone corresponding to the first receiving space.

14. The keypad assembly of claim 13, wherein the crown comprises a bottom end and a tapered end, and the tapered end is opposite to the bottom end and away from the first surface of the crown.

15. The keypad assembly of claim 14, wherein the bottom end has a radius equal to that of the opening of the first receiving space.
